(19) United States
(12) Patent Application Publication
(10) Pub. No.: US 2010/0140587 A1
(43) Pub. Date: Jun. 10, 2010

(54) High-Injection Heterojunction Bipolar Transistor

(76) Inventors: Daniel N. Carothers, Oro Valley, AZ (US); Andrew T.S. Pomerene, Leesburg, VA (US)

Correspondence Address: BAE SYSTEMS, PO BOX 868, NASHUA, NH, 03061-0868, US

(21) Appl. No.: 12/523,807

(22) PCT Filed: Oct. 16, 2008
(86) PCT No.: PCT/US08/80160

§ 371 Date: Feb. 9, 2010

Related U.S. Application Data
(60) Provisional application No. 61/001,140, filed on Oct. 31, 2007.

(51) Int. Cl. H01L 29/737; H01L 31/18; H01L 21/331

(52) U.S. Cl. 257/14; 438/59; 438/312; 257/197; 257/E29.188; 977/755; 257/E31.052; 257/E21.371

(57) ABSTRACT

A method for manufacturing high-injection heterojunction bipolar transistor capable of being used as a photonic device is disclosed. A sub-collector layer is formed on a substrate. A collector layer is then deposited on top of the sub-collector layer. After a base layer has been deposited on top of the collector layer, a quantum well layer is deposited on top of the base layer. An emitter is subsequently formed on top of the quantum well layer.

### PRIORITY CLAIM

The present application claims benefit of priority under 35 U.S.C. §365 to the previously filed international patent application number PCT/US08/080160 filed on Oct. 16, 2008, assigned to the assignee of the present application, and having a priority date of Oct. 31, 2007, based upon U.S. provisional patent application No. 61/001,140. The contents of both applications are incorporated herein by reference.

### BACKGROUND OF THE INVENTION

1. Technical Field

The present invention relates to bipolar transistors in general, and in particular to high-injection heterojunction bipolar transistors capable of being used as photonic devices.

2. Description of Related Art

Much efforts have been invested in applying standard heterojunction bipolar transistor (HBT) technology to the field of photonics to produce heterojunction phototransistors. Like a dedicated photodiode, heterojunction phototransistors can convert optical signals into electrical signals because heterojunction phototransistors employ materials with designed bandgaps capable of absorbing light in a given band.

While heterojunction phototransistors share many of the benefits of HBTs operating in the electronic domain, heterojunction phototransistors also suffer from the operational limitations of HBTs such as:
i. requirement of thin base/collector layers to lower carriers transit time;
ii. low doping levels in high base resistance leads to emitter crowding and reduction in frequency due to increase in RC constant;
iii. collectors require elevated doping levels in bandgap narrowing leads to reduction in γ and reduction in frequency due to increase in storage time;
iv. device areas need to be reduced in order to minimize base/collector capacity;
v. Kirk effect that corresponds to the reduction of the collector field;
vi. Avalanche effect that can occur at the end of collectors can lead to device destruction; and
vii. base carrier recombination reduces gain, and thermal effects, including hysterysis, that lead to high power operation.
   Conventional HBT designs also suffer from high injection effects that can be exaggerated when the emitter-base junction is illuminated. These phenomena lead to an increase in majority carrier concentration at the base of a heterojunction phototransistor, resulting in an increased electron current from the base to the emitter, which leads to a reduction in γ and a corresponding drop in β.

Consequently, it would be desirable to provide improved heterojunction phototransistors that allow better device performance over a wider scope of operation as photonic devices.

### SUMMARY OF THE INVENTION

In accordance with a preferred embodiment of the present invention, a sub-collector layer is formed on a substrate. A collector layer is then deposited on top of the sub-collector layer. After a base layer has been deposited on top of the collector layer, a quantum well layer is deposited on top of the base layer. An emitter is subsequently formed on top of the quantum well layer.

All features and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIGS. 1a-1b are diagrams of a heterojunction bipolar transistor according to the prior art and a high-injection heterojunction bipolar transistor in accordance with a preferred embodiment of the present invention, respectively;

FIG. 2 is a schematic diagram of a high-injection heterojunction bipolar transistor operating as a photodetector; and

FIGS. 3a-3h are process flow diagrams of a method for fabricating a high-injection heterojunction bipolar transistor, in accordance with a preferred embodiment of the present invention.

### DETAILED DESCRIPTION OF A PREFERRED EMBODIMENT

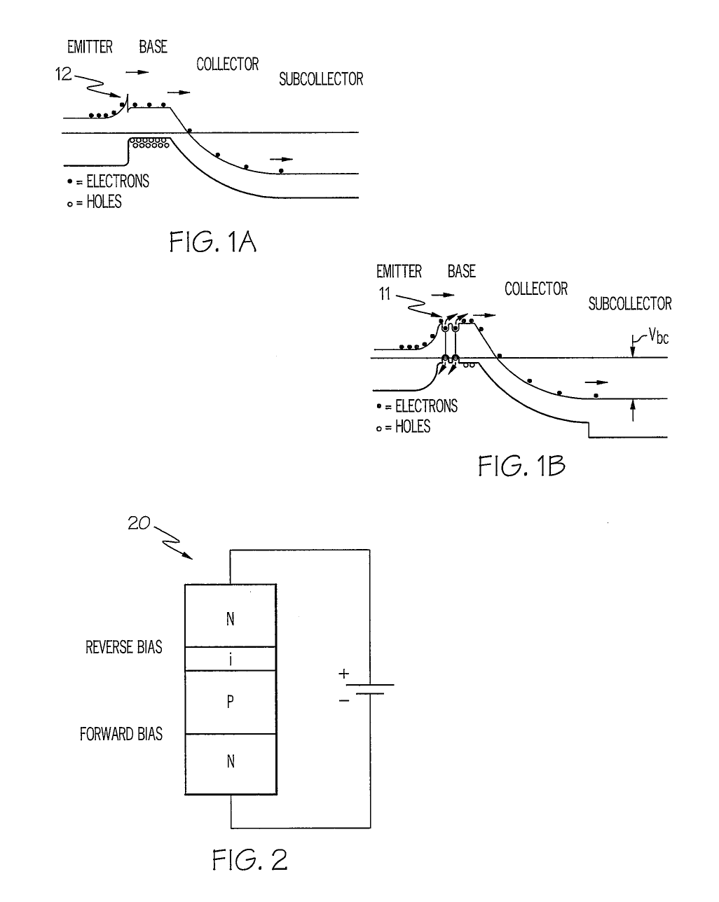

Referring now to the drawings and in particular to FIGS. 1a-1b, there are depicted diagrams of a conventional heterojunction bipolar transistor (HBT) and a high-injection heterojunction bipolar transistor (HI-HBT) of the present invention, respectively. The difference between the HBT in FIG. 1a and the HI-HBT in FIG. 1b is a quantum well added between an emitter and a base of the HI-HBT. The addition of the quantum well can be represented by a potential barrier 11, as shown in FIG. 1b. Potential barrier 11 will not only allow the optical properties of the quantum well to be tailored, it also provides numerous other advantages to the photonic operations of the HI-HBT itself. The insertion of the quantum well between the emitter-base junction of the HI-HBT can enhance the valence band discontinuity. As a result, the HI-HBT can achieve a higher emitter injection efficiency.

The quantum well can be extended by encasing it with wider band gap barriers. These barriers can constrain the quantum well parameters and limit the hole injection into the emitter. As a result, the injection of electrons across the emitter-base junction can be controlled.

The presence of the quantum well in the emitter-base junction of the HI-HBT should greatly lessen or eliminate the expected potential spike, such as a spike 12, in the conventional HBT of FIG. 1a. This can reduce the detrimental offset voltage while maintaining a high-current gain simultaneously. The high-current gain at the quantum well can improve the operation of HI-HBTs functioning as photonic devices.

HI-HBTs can be functioned as photonic devices such as photodetectors, modulators or lasers. The ultimate flexibility of HI-HBTs comes from the level of integration that can be achieve by employing them in a photonic integrated circuit. In most single layer integration schemes, there are performance tradeoffs that must be made to allow full integration. For example, an optimized PiN photodiode or modulator will make a weak laser, while a well optimized laser will result in a poorly performing detectors and high Vπ modulators. HI-HBTs bring the advantage of a three-terminal operation and structure, which allows for greater control over high injection effects and field formation.

With reference now to FIG. 2, there is illustrated a schematic diagram of a HI-HBT operating as a photodetector, in accordance with a preferred embodiment of the present invention. As shown, a HI-HBT 20 is configured for a two-terminal operation during which the NP junction is forward-biased and the PiN-junction is reverse-biased. Since the reverse-biased PiN-junction has a much larger resistance than the forward-biased NP-junction, most of the voltage drop occurs across the PiN-junction. When HI-HBT 20 functions as a photodetector, the detected photocurrent exhibits phototransistor gain due to external carrier injection, which can be further enhanced through the usage of a third terminal (not shown).

The ability to control large electron concentrations at the quantum well of HI-HBT 20 in a forward-biased configuration can achieve efficient lasing and possible amplification. Also, the ability to quickly modulate large biasing electric fields in a reverse-bias configuration allows high-frequency modulation and detection of radiation. This will also affect photo detections when HI-HBT 20 is being operated as a three-terminal device by ensuring that the best gain-bandwidth product can be obtained. When HI-HBT 20 is being operated as a three-terminal device, the base potential can be kept constant. However, when HI-HBT 20 is being operated as a two-terminal device with a floating base, holes are accumulated in the base, resulting in a base/emitter barrier diminution.

The presence of a quantum well within HI-HBT 20 enables excellent transistor characteristics that will result from the enhanced valence band discontinuity (ΔEᵥ) when HI-HBT 20 is operating in a normal operating mode. Thus, the placement of a quantum well between the base and emitter of HI-HBT 20 can achieve both high emitter injection efficiency and reduced offset voltage.

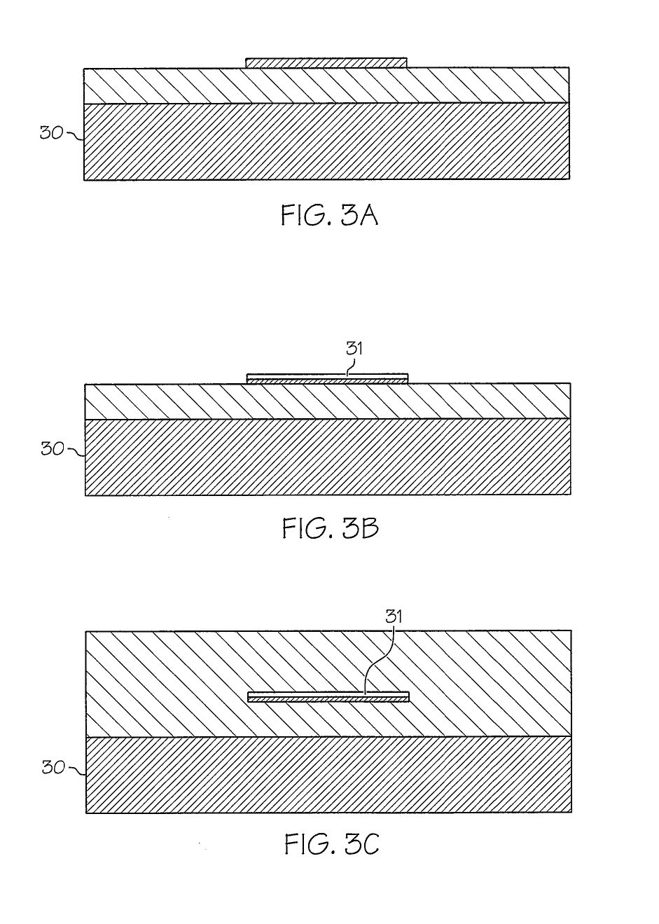

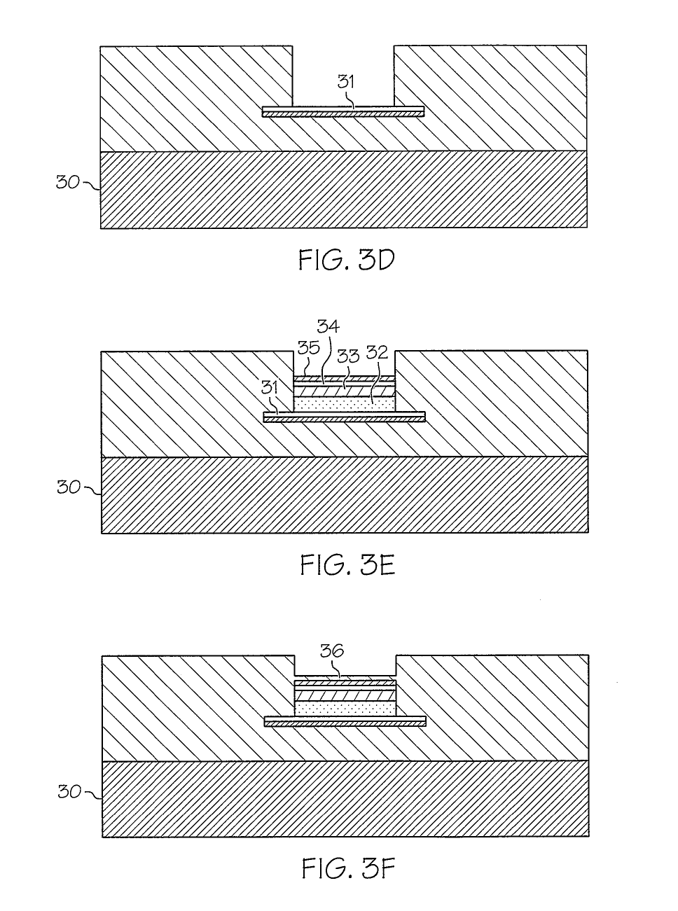

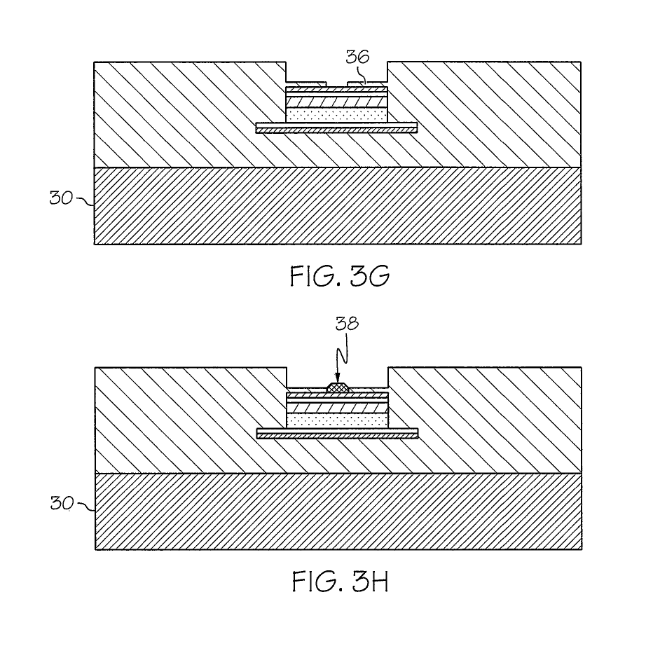

Referring now to FIGS. 3a-3i, there are illustrated process flow diagrams of a method for fabricating a HI-HBT, in accordance with a preferred embodiment of the present invention. Starting with a silicon-on-insulator substrate 30, the top silicon layer is patterned and etched, as shown in FIG. 3a. Either N+ or P+ (such as phosphorous or boron) implants are then performed on the top silicon layer of substrate 30 to produce a sub-collector layer 31, as depicted in FIG. 3b.

Next, a layer of oxide is then deposited on substrate 30 to cover sub-collector layer 31, as shown in FIG. 3c. The layer of oxide is preferably 100 Å thick.

An opening is then made within the oxide layer to form a selective growth surface on sub-collector layer 31, as depicted in FIG. 3d.

A collector layer 32 is deposited (or grew) on top of sub-collector layer 31. The dopant of collector layer 32 is the same as that of sub-collector layer 31. A compositionally grated germanium is added during the formation of collector layer 32. The concentration of germanium is preferably from 25% to 40%. Collector layer 32 is preferably 500-1000 Å thick.

A base layer 33 is then deposited on top of collector layer 32. Base layer 33 is preferably 50-400 Å thick. Afterwards, a silicon-germanium (Ge=50% or greater) quantum well layer 34 is deposited on top of base layer 33. Quantum well 34 is preferably a type I well of 30-100 Å thick. Next, a silicon layer 35 is deposited on top of quantum well layer 34 as a terminating surface. Silicon layer 35 is preferably 6-10 Å thick. All layers 31-35 are preferably deposited via chemical vapor depositions. As a result, an N—P-i or a P—N-i structure is formed on substrate 30, as shown in FIG. 3e.

A thin oxide layer 36 is deposited on top of silicon layer 35, as depicted in FIG. 3f. Thin oxide layer 36 is preferably 200 Å thick. Thin oxide layer 36 is then patterned and etched to open a window, as shown in block 3g.

An emitter 38 is grew on top of silicon layer 35, as depicted in FIG. 3h. Emitter 38 is preferably 500-1000 Å thick. As a result, either an N—P-i-N or a P—N-i-P structure is formed on substrate 30.

As has been described, the present invention provides a method for manufacturing HI-HBTs capable of being used as photonic devices. With the present invention, one or more quantum wells are inserted between an emitter and a base to form a P-i-N structure that will exhibit phototransistor gain. The monolithically integrated HI-HBT having a quantum well with a type II band alignment between the base and emitter can control the transfer of charge based on photo absorption within the quantum well. The HI-HBT allows gain to be imparted to detect photons based on the actual transistor action, which also allows gain at lower voltages to permit direct compatibility with existing electronic components.

While the invention has been particularly shown and described with reference to a preferred embodiment, it will be understood by those skilled in the art that various changes in form and detail may be made therein without departing from the spirit and scope of the invention.

What is claimed is:

1. A method for manufacturing a high-injection heterojunction bipolar transistor capable of being used as a photonic device, said method comprising:
forming a sub-collector layer on a substrate;
depositing a collector layer on top of said sub-collector layer;
depositing a base layer on top of said collector layer;
depositing a quantum well layer on top of said base layer; and
forming an emitter on top of said quantum well layer.

2. The method of claim 1, wherein said sub-collector layer is formed by N+ implants.

3. The method of claim 1, wherein said sub-collector layer is formed by P+ implants.

4. The method of claim 1, wherein said depositing steps are performed by chemical vapor depositions.

5. The method of claim 1, wherein said quantum well layer is formed by silicon-germanium.

6. The method of claim 1, wherein said emitter is formed by N+ implants.

7. The method of claim 1, wherein said emitter is formed by P+ implants.

8. A high-injection heterojunction bipolar transistor comprising:
a collector;
an emitter;
a base; and
at least one quantum well located between said emitter and said base.

9. The high-injection heterojunction bipolar transistor of claim 8, wherein said base, said at least one quantum well, and said emitter form a P-i-N structure.

10. The high-injection heterojunction bipolar transistor of claim 8, wherein said emitter, said at least one quantum well, and said base form a P-i-N structure.
